(19) United States
(12) Patent Application Publication
(10) Pub. No.: US 2001/0001385 A1
(43) Pub. Date: May 24, 2001

(54) Boron-doped isotopic diamond and process for producing the same

(75) Inventors: Kazuo Nakamura, Yokohama-shi (JP); Kenji Horiuchi, Kawasaki-shi (JP); Satoshi Yamashita, Tokyo (JP); Kazuhiro Kataoka, Tokorozawa-shi (JP)

Correspondence Address: FLYNN, THIEL, BOUTELL & TANIS, P.C., 2026 Rambling Road, Kalamazoo, MI, 49008-1699, US

(73) Assignee: TOKYO GAS CO., LTD

(21) Appl. No.: 09/732,799

(22) Filed: Dec. 8, 2000

Related U.S. Application Data
(63) Continuation-in-part of application No. 09/123,842, filed on Jul. 28, 1998.

(30) Foreign Application Priority Data
Aug. 1, 1997 (JP) 9-221136
Nov. 29, 1997 (JP) 9-344037

(51) Int. Cl. C30B 23/00

(52) U.S. Cl. 117/84

(57) ABSTRACT

A ¹²C or ¹³C isotopic diamond which is boron-doped and has an extremely high thermal conductivity, and a process for producing the same. The purity of the ¹²C or ¹³C isotope of said isotopic diamond is preferably at least 99.5%.

### BACKGROUND OF THE INVENTION

1. Field of the Invention

The present invention relates to a ¹²C isotopic diamond or a ¹³C isotopic diamond which is boron-doped and has a high thermal conductivity, and a process for producing the same. In the present specification, a diamond purified to ¹²C (namely, in the isotopic ratio, the amount of ¹²C in the purified diamond is increased to more than that of a natural diamond) is referred to as a ¹²C diamond or a ¹²C isotopic diamond properly.

2. Prior Art

Since diamond has the highest hardness (Mohs hardness: 10) in known substances and an outstanding abrasion resistance, it is employed for tools such as a whetstone, an abrasive material, a die, a boring bit, a cutting tool, a coating tool and the like. In addition, since it has a high velocity of sound, it is utilized for a high-sound-generating speaker diaphragm.

Moreover, diamond has the highest thermal conductivity in all substances at room temperature, and this characteristic is exhibited more at a higher purity. Hence, it is combined into electronic parts as a heat sink material. However, since diamond is an electrically insulating material itself, it has been limited to a simple application such as said heat sink material.

A carbon or a carbon compound present in nature contains about 1.1% of ¹³C in addition to ¹²C, and this is also true of a natural diamond. It is known that a diamond with a purified carbon isotope has an improved thermal conductivity as compared with a diamond with a natural ratio. For example, in “Physical Review B”, Vol. 42, No. 2, pp. 1104-1111 (Jul. 15, 1990), it is reported that a diamond with ¹²C of 99.93% is synthesized employing 99.9% ¹²CH₄, and that said diamond has a thermal conductivity about 1.5 times as high as that of a diamond with a natural isotopic composition.

According to the report, a ¹²C diamond single crystal is synthesized as a sample thereof by preparing a diamond sheet according to the CVD method employing a 99.9%-enriched ¹²CH₄, pulverizing the sheet into a powder, and growing the crystal on a small diamond seed crystal from a molten transition metal at a pressure of 52000 atm. and a temperature of 1200° C. According to the above method of synthesis, it is necessary, first of all, to prepare a diamond powder as a carbon source according to the CVD method. However, the yield according to the CVD method is generally of the order of 1%, hence, even if the above material is employed, a process of obtaining a powder thereof is also needed in order to synthesize a diamond single crystal, and besides, there exists a large problem regarding the yield thereof.

The thermal conductivity of diamond is very liable to be influenced by crystal quality, and also in the case of a ¹²C isotopic diamond, if the crystal quality is poor, it is difficult to generate a high thermal conductivity according to ¹²C purity. In addition, it is known that if diamond contains impurities, such as nitrogen or impurities being added thereto, the thermal conductivity decreases. Japanese Patent Publication No. 4-92894 reports that a synthesized diamond with a high thermal conductivity is obtained by applying a gas phase synthesis technique, employing ¹²C or ¹³C wherein more than 99.9% of the carbon is carbon isotopes, and adjusting the incorporation of nitrogen to less than 20 ppm.

In addition, it is known that diamond is doped with boron to be a p-type semiconductor and a boron-doped diamond is expected to be employed as a semiconductor device and a luminescent device. However, boron doped to the diamond becomes an impurity to the diamond. Because of this, it has been thought to be difficult for a ¹²C isotopic diamond sensitive to crystal quality to express a high thermal conductivity, and this is also true of a boron-doped diamond and, needless to say, a boron-doped ¹²C isotopic or ¹³C isotopic diamond.

That is, it has been thought that a dopant, boron, scatters phonons, a main factor in the conduction of heat in a diamond, and that, in a boron-doped and isotopically purified diamond, the improvement in thermal conductivity is small. For this point, for example, when a boron-doped diamond is applied to a semiconductor device or an optical material as an example of application, it may cause heat concentration and it has been thought that, in such a case, the effect of a high thermal conductivity according to isotopic purity cannot be utilized because of the above point.

### SUMMARY OF THE INVENTION

When the present inventors actually synthesized a boron-doped and isotopically purified ¹²C isotopic diamond and measured the thermal conductivity thereof, they unexpectedly found that it retained the electrical conductivity of a p-type semiconductor according to the addition of boron and a high thermal conductivity according to ¹²C purity. That is, the present invention provides a ¹²C or ¹³C isotopic diamond which is boron-doped, is isotopically purified and has a high thermal conductivity of about 15-50%, preferably 30-50%, higher than that of a high-purity diamond having a natural isotopic ratio at room temperature and a process for producing the same.

The present invention provides a ¹²C or ¹³C isotopic diamond which is boron-doped, has a high thermal conductivity and is isotopically purified, and it also provides a luminescent device comprising a ¹²C or ¹³C isotopic diamond which is boron-doped, has a high thermal conductivity and is isotopically purified. Moreover, the present invention provides a semiconductor device comprising a ¹²C or ¹³C isotopic diamond which is boron-doped, has a high thermal conductivity and is isotopically purified.

In addition, the present invention provides a process for producing a ¹²C or ¹³C isotopic diamond single crystal, wherein a diamond single crystal is formed on a seed crystal diamond by using a carbon comprising isotopically purified ¹²C or ¹³C as a material, employing a flux containing a nitrogen getter, adding boron into said material or the flux, or around said material and the flux, and diffusing said carbon material into the flux under a high pressure and a high temperature. Moreover, the present invention provides a process for producing a ¹²C or ¹³C isotopic diamond which is boron-doped and has a high thermal conductivity, wherein a diamond is formed in a thin-film state on a substrate placed in a reaction atmosphere by employing a mixed gas of an isotopically purified hydrocarbon or carbon monoxide or carbon dioxide by ¹²C or ¹³C or at least two thereof, and hydrogen as a material, and adding a doping component thereto.

### BRIEF DESCRIPTION OF THE DRAWINGS

FIG. 1 is a view showing one example of a sample constitution according to the temperature gradient method.

FIG. 2 is a view of the sample constitution employed in the present examples.

FIG. 3 is a view showing the ultrahigh-pressure device employed in the present examples.

### PREFERRED EMBODIMENTS OF THE INVENTION

A ¹²C isotope or a ¹³C isotope in a diamond according to the present invention needs to have a purity (degree of isotopic purification) of at least 99.5%, preferably at least 99.9%, more preferably at least 99.94%. In the present invention, a p-type semiconductor can be obtained by doping boron to an isotopically purified ¹²C isotopic diamond or ¹³C isotopic diamond, and said p-type semiconductor has a high thermal conductivity of from about 26-31 W/cm ° K or about 15-50%, preferably 30-50%, higher than that of a high-purity diamond having a natural isotopic ratio at room temperature.

Here, the amount of boron doped is not particularly restricted so long as it is in an amount allowing a function as a p-type semiconductor to be exhibited. Preferably it is less than 100 ppm, more preferably less than 60 ppm, and according to the amount of boron added where the thermal conductivity (half-band width of a Raman spectrum) begins to decrease, it is preferably of the order of 30-40 ppm to about 3-4 ppm, or less.

As described above, boron doped to diamond becomes an impurity to the diamond, and hence, it has been thought to be hard for a ¹²C diamond sensitive to crystal quality to express a high thermal conductivity.

In the present invention, completely inversely to such a perception or technical common knowledge, a p-type semiconductor can be obtained by doping boron to an isotopic diamond comprising isotopically purified ¹²C or an isotopic diamond comprising isotopically purified ¹³C, and besides, said p-type semiconductor has a high thermal conductivity of from about 26-31 W/cm ° K.

Hence, a boron-doped ¹²C diamond according to the present invention is an excellent material as a material related to heat such as a semiconductor device and a luminescent device.

Examples of a process for the production of a diamond include a gas phase method and a high-pressure method. A diamond which is boron-doped, has a high thermal conductivity and is isotopically purified according to the present invention can be produced by any one of these methods. Of them, the gas phase method comprises employing a mixed gas of a hydrocarbon gas, such as methane or carbon monoxide or carbon dioxide or a mixed gas of at least two thereof, and hydrogen as a material, applying a gas phase reaction, for example, a CVD method or a plasma CVD method, and forming a diamond in a thin-film state on a substrate such as a silicon wafer placed in a reaction atmosphere. A diamond according to the present invention is produced in the same manner employing these isotopically purified materials. For example, a diamond is produced by employing ¹²CH₄ or ¹³CH₄ isotopically purified to 99.5% or more as a material and adding boranes and the like as a doping component.

Examples of the high-pressure method include a shock wave high-pressure method and a static high-pressure method, and examples of the static high-pressure method include a direct conversion method and a flux method. Of them, the direct conversion method is a method of directly converting a graphite simple substance into a diamond by applying a high temperature and a high pressure thereonto and the flux method is a method of precipitating a diamond after dissolving a carbon into a molten metal (including alloys) such as Fe, Co and Ni. Examples of the flux method include a film growth method and a temperature gradient method. The film growth method is a method utilizing the fact that graphite and diamond have a different solubility in molten metals, wherein when a molten metal and graphite come into contact with each other at a high pressure, the graphite is dissolved and diffused, and just after then (at the rear of the molten metal film) a diamond is precipitated.

On the other hand, the temperature gradient method is a method utilizing the fact that diamond has a different solubility in molten metals according to a temperature (temperature difference: about from 20 to 50° C.), wherein, to the molten metal phase heated at a high pressure, one is retained at a high temperature to dissolve a carbon material, while the other is retained at a lower temperature to precipitate a diamond. In the temperature gradient method, large grains of diamond are grown on a diamond seed crystal placed at a low temperature region, wherein the formation of spontaneous nuclei occurring is suppressed and the dissolution of the seed crystal is suppressed till the occurrence of diamond growth by arranging a diamond nucleation suppressing layer and an isolation layer at the upper part of the seed crystal.

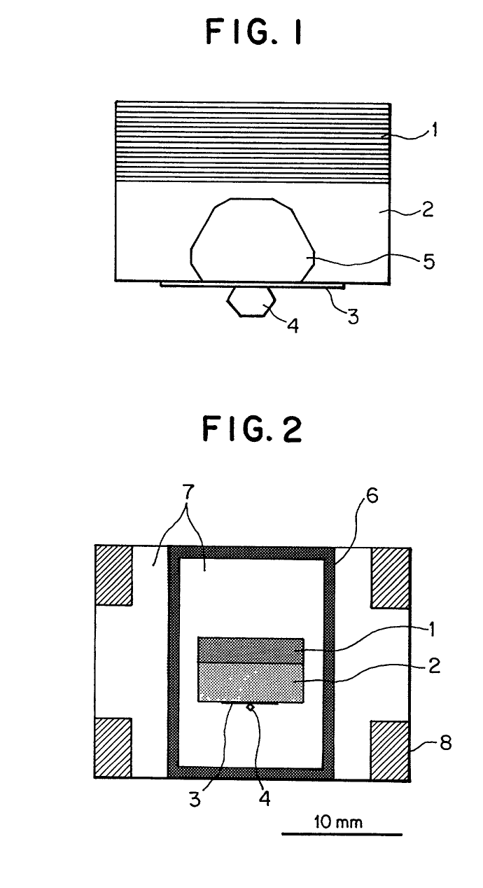

FIG. 1 shows an example of “the sample constitution” and the like introduced heretofore for the above temperature gradient method (“Technology for Treating Resources”, Vol. 37, No. 1 (90, spring), pp. 23-28). In FIG. 1, 1 indicates a carbon source, 2 is a metal solvent, 3 is platinum foil, and 4 is a diamond seed crystal. The constitutional sample is put into a capsule of an NaCl molded article, and the capsule is packed in a cylindrical heater so that the carbon source should be at the center of the heater. In the cylindrical heater, the central part has a high temperature and both ends have a low temperature, and hence the metal solvent can have a temperature gradient according to this temperature distribution.

Subsequently, the capsule is packed in a high-pressure vessel, pressed to about 60,000 atm., heated to about 1400° C. for from 15 to 24 hours, and thereby a crystal of from 2 to 3 mm as shown with the mark 5 in FIG. 1 is obtained. It is described that, in this case, the above platinum foil 3 is for protecting the seed crystal lest the seed crystal dissolve in the metal solvent to disappear at the time of the start of crystal growth. According to the above document, the platinum foil 3 dissolves in the metal solvent to disappear gradually with time, but the metal solvent is saturated with carbon at this time, and hence the diamond seed crystal 4 does not dissolve.

In the case of synthesizing a diamond single crystal by the temperature gradient method, a diamond, graphite or a mixture thereof is employed as a carbon source. In the present invention, also in the case of producing a ¹²C or ¹³C isotopic diamond single crystal by the temperature gradient method, these carbons may be employed as a carbon source. However, a pyrolytic carbon, a diamond synthesized by chemical deposition or a diamond-like carbon synthesized by chemical deposition is preferably employed.

For example, Japanese Patent Publication No. 4-108532 suggests a technique of producing a single crystal diamond with a high isotopic purity and a high thermal conductivity by the same temperature gradient method by preferably employing a diamond obtained by the CVD (chemical vapor deposition) method as a carbon source. Moreover, according to Japanese Patent Publication No. 5-200271, an IIb-type diamond powder containing boron as an isolated substitution-type impurity is employed as a carbon source and a diamond single crystal having semiconductor characteristics is grown by the temperature gradient method, which is related to a diamond with a natural isotopic ratio and has no consideration about thermal conductivity characteristics, and hence is different from the present invention fundamentally in these points.

In addition, a pyrolytic carbon may be employed as a carbon source, however, in this case, generally a pretreatment is indispensable. As the pretreatment a technique employed comprising pressing, for example, a pyrolytic carbon powder, by means of a steel die, putting it in a graphite capsule, and heating it by means of an induction heating furnace under a vacuum to a temperature of from 1800 to 2000° C. to perform annealing. However, if a flake-like pyrolytic carbon is employed as a carbon source, a single crystal diamond can be obtained without requiring such a pretreatment (Japanese Patent Publication No. 8-141385). Said flake-like pyrolytic carbon has the characteristics shown in Table 1. (Table 1 describes also the characteristics of a soot-like pyrolytic carbon for comparison.)

The above flake-like pyrolytic carbon is obtained by thermally decomposing high-concentration methane, ethane, propane, benzene, acetylene, other hydrocarbon gases, or carbon monoxide (including the case of a hydrocarbon gas or carbon monoxide with a concentration of 100% without a carrier gas) in a furnace. For example, in the case of methane, at a decomposition temperature of from 1800 to 2000° C. and at a pressure in the furnace of from 1 to 5 Torr to form a deposit on a substrate, such as a graphite sheet, and then releasing it from the substrate. In Table 1, the BAF value is obtained by employing an X-ray diffraction technique, and the larger the numerical value, the larger the anisotropy. The BAF value of ordinary graphite is less than 2.

TABLE 1

| | | | | | Lattice |
|---|---|---|---|---|---|
| | | Density | BET | | constant |
| Kind of | Structure by | (bulk | surface | | of |
| pyrolytic | optical | density) | area | BAF | C axis |
| carbon | microscope | (g/cm³) | (m²/g) | value | (AÅ) |
| Flake-like | Columnar | 1.10 | 3.1 | 3˜20 | 6.8˜7.0 |
| Soot-like | Non-columnar | 0.87 | 55.6 | about 1 | 6.8˜7.0 |

In the present invention, in the case of employing a flake-like pyrolytic carbon as a carbon source, a diamond containing ¹²C or ¹³C at a high ratio can be produced by selecting the ratio of a carbon isotope in a hydrocarbon gas material or a carbon monoxide material, for example, the ratio of ¹²C or ¹³C in methane, at the time of producing a flake-like pyrolytic carbon, namely, by employing methane with a varied isotopic composition.

The pressure and temperature to be applied in the performance of the present invention is not particularly restricted so long as they are within the conditions of a diamond stable region, preferably, it can be performed at a pressure of from about 5 to 6.5 GPa and at a temperature of from about 1300 to 1500° C. As a flux, any metal or alloy (including mixtures) known as those used in the flux method can be employed. Preferably Fe, Co, Ni and alloys of these metals can be employed, and a component as a boron source, for example, boron, is added thereto. Moreover, a diamond not containing nitrogen as an impurity or substantially not containing nitrogen can be obtained by employing a flux containing a nitrogen getter (Ti, Zr, Al and the like) on demand.

### EXAMPLES

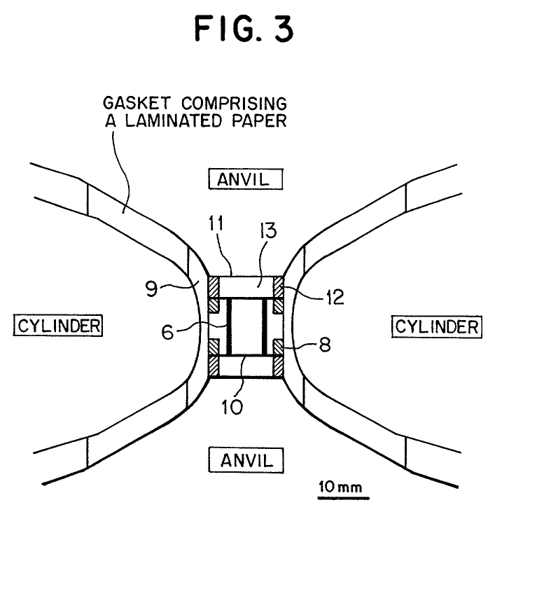

Hereafter, the present invention will be described in more detail according to examples. It goes without saying that the present invention is not restricted to these examples. Examples according to the temperature gradient method will be described but the same can be applied to the gas phase method. FIG. 2 and FIG. 3 show the sample constitution and the ultrahigh-pressure device employed in the present examples respectively.

As shown in FIG. 2, the sample constitution is almost similar to the sample constitution shown in FIG. 1, and the same marks are used about common parts in FIG. 1 and FIG. 2. 1 shows a carbon source, 2 is a metal solvent (=flux), 3 is a platinum foil, and 4 is a diamond seed crystal. The platinum foil 3 is placed between the diamond seed crystal 4 and the flux 2, and prevents the seed crystal 4 from dissolving at the initial stage of the production operation. In addition, 6 shows a graphite heater, 7 is a pressure medium, and 8 is an iron sealing ring for sealing the pressure medium 7 provided therearound. In the present examples, a metal solvent containing a nitrogen getter was employed as the flux 2, and “NaCl+10 wt. % ZrO₂” as the pressure medium 7 for transmitting the pressure uniformly.

When the sample constitution (sample constituted as above) is retained under the condition where the diamond is stable and under the conditions of a high temperature and a high pressure for the flux to dissolve, a diamond single crystal grows on a seed crystal. In the case of employing a cylindrical heater, the central part thereof has a relatively high temperature and the upper and lower circumference thereof has a low temperature, hence, utilizing this feature, a temperature difference can be made between the central side (high temperature) and the lower side (low temperature) of the flux. For this, the carbon source is placed so that it should be located at the central part, namely, the high-temperature part, and thereby the carbon material at the upper side at a high temperature is dissolved in the flux and precipitated as a diamond single crystal on the seed crystal at the lower side at a low temperature.

FIG. 3 shows the cross-section of a so-called flat-belt-type ultrahigh-pressure device employed in the present examples. As shown in the drawing, the device essentially comprises cylinders and anvils of an ultrahard alloy, and 9 in FIG. 3 shows a gasket. The gasket 9 is for sealing between the anvils and the cylinders, and in the present examples, pyrophyllite is employed as a material for it.

The sample composition is placed between the space formed by the cylinders and the anvils as shown in FIG. 2, and heating is performed by running an electric current from the anvil to the graphite heater 6 through a stainless steel electrode 11, an electroconducting ring (iron) 12 and a molybdenum electrode 10. On the top and the bottom of the graphite heater 6 are provided zirconia plates 13 for insulation.

### Examples

A diamond single crystal according to the present invention was produced by employing the sample constitution of FIG. 2 and the ultrahigh-pressure device of FIG. 3. As a carbon source was employed a product obtained by thermally decomposing an isotopically purified ¹²C methane gas (¹²CH₄, purity: more than 99.95%) obtained from LNG by rectification without employing a carrier gas (namely, 100% methane) at a decomposition treatment temperature of 1900° C. and at a pressure in the furnace of 2 Torr, depositing it on a graphite substrate and releasing it therefrom. It has a columnar structure according to an optical microscope, a bulk density of 1.10 g/cm³, a BAF value of 5 and a BET surface area of 3.1 m²/g.

Boron was added (amount of addition: 1000 ppm) to 231 mg of this flake-like pyrolytic carbon, and the mixture was employed as the carbon source 1. The above carbon source 1 was placed on the flux 2 of a metal solvent containing a nitrogen getter to form a sample composition as shown in FIG. 2, and this sample composition was placed in the cylinders in FIG. 3.

Thereafter, the pressure medium 7 was pressed to 6.3 GPa by upper and lower anvils. After pressing, an electric current (AC, 2.69 V, 664 A (ampere)) was run to the graphite heater 6 through the stainless steel electrode 11, the electroconducting ring 12 and the molybdenum electrode 10 to heat it to 1450° C. In this case, the operation temperature was calibrated by a Pt/Pt 13% Rh thermocouple.

After the above operation state was maintained for 110 hours, the electric current was cut and then the pressing state was released to obtain a diamond single crystal. The produced diamond had a weight of 76.4 mg, and the facets on the surface of the crystal were mainly {100} and {111}. In the same manner as above, diamond single crystals were produced by employing products obtained by adding boron of 1000 ppm, 3000 ppm, 1%, 3% and 10% (mol) respectively to a flake-like pyrolytic carbon obtained from a ¹²C methane gas as a carbon source.

### Comparative Examples

In the same manner as the above technique, a non-boron-doped (namely, produced without adding boron to a carbon source) diamond with a natural isotopic ratio (¹²C=98.9%), a boron-doped (namely, produced by adding boron to a carbon source) diamond with a natural isotopic ratio (¹²C=98.9%), and a non-boron-doped ¹²C diamond (¹²C=99.95% or more) were produced. The amount of boron and the thermal conductivity of each of the thus obtained diamonds were measured. The thermal conductivity here was measured by the following measurement 1.

### Measurement of the Amount of Boron

Employing a microscopic Fourier transform infrared spectrometer (Janssen Micro FTIR Spectrometer, manufactured by JASCO corporation) as a device, the quantitative determination of boron was conducted according to the strength of the absorption peaks of 1280 cm⁻¹ and 2800 cm⁻¹ by boron in the diamonds. The amount of boron contributing to the electrical conductivity in the diamonds (effective acceptor density) is determined by this method. In Table 2, the concentration of boron shows the above measured values. Table 2 also shows the amounts of boron added to the carbon material source (amounts of boron incorporated into the material).

### Measurement of Thermal Conductivity 1

The FWHM (full width at half maximum) of a Raman peak indirectly has a correlation with thermal conductivity, and it is thought that, in a diamond with a high crystal quality, the smaller the FWHM of a Raman peak is, the higher the suggested thermal conductivity. The measurement of a Raman spectrum was conducted by a laser Raman spectrometer (NR-1800 model, manufactured by JASCO corporation). As a light source was employed an argon laser with a wavelength of 514.53 nm, and the output power was 200 mW. Since the peak of a diamond appears around 1333 cm⁻¹, the measurement of the FWHM thereof was conducted. The resolving power in the present measurement seems to be of the order of 0.2 cm⁻¹ according to measurement conditions such as a diffraction grating (1800/mm) and a slit width (20 μm).

Table 2 shows the results of the measurement. Examples 1-5 in Table 2 show typical examples of the results obtained by the above measurements.

TABLE 2

| | | Amount | | FWHM | |
|---|---|---|---|---|---|
| | | of Boron | Concen- | (full width at | |
| | Kind of | in Carbon | tration | half maximum) | |
| No. | Diamond | Source | of Boron | of Raman peak | |
| Comp. | Diamond | −−− | −−− | 1.73 | cm⁻¹ |
| Ex. 1 | with natural | | | | |
| | isotopic ratio | | | | |
| | (¹²C = 98.9%) | | | | |
| Comp. | Diamond | 1000 | 3˜4 ppm | 1.73 | cm⁻¹ |
| Ex. 2 | with natural | ppm | | | |
| | isotopic ratio | | | | |
| | (¹²C = 98.9%) | | | | |
| Comp. | Diamond | 3000 | 9˜19 ppm | 1.73 | cm⁻¹ |
| Ex. 3 | with natural | ppm | | | |
| | isotopic ratio | | | | |
| | (¹²C = 98.9%) | | | | |
| Comp. | ¹²C diamond | −−− | −−− | 1.54 | cm⁻¹ |
| Ex. 4 | (¹²C = 99.95% | | | | |
| | or more) | | | | |
| Example | ¹²C diamond | 1000 | 3˜4 ppm | 1.54 | cm⁻¹ |
| 1 | (¹²C = 99.95% | ppm | | | |
| | or more) | | | | |
| Example | ¹²C diamond | 3000 | 9˜19 ppm | 1.54 | cm⁻¹ |
| 2 | (¹²C = 99.95% | ppm | | | |
| | or more) | | | | |
| Example | ¹²C diamond | 1% | 29˜38 ppm | 1.55˜1.59 | cm⁻¹ |
| 3 | (¹²C = 99.95% | | | | |
| | or more) | | | | |
| Example | ¹²C diamond | 3% | 90˜105 ppm | 1.57˜1.70 | cm⁻¹ |
| 4 | (¹²C = 99.95% | | | | |
| | or more) | | | | |
| Example | ¹²C diamond | 10% | === | 1.8 | cm⁻¹ |
| 5 | (¹²C = 99.95% | | | | |
| | or more) | | | | |

Note
−−−: Nil
===: Unmeasured

As shown in Table 2, the FWHM of the Raman spectrum of the comparative example, namely, the ¹²C diamond (¹²C=99.95% or more), is 1.54 cm⁻¹, which corresponds to a thermal conductivity of about 31 W/cm K. In contrast, all of the ¹²C diamond (¹²C=99.95% or more) of Example 1, the ¹²C diamond (¹²C=99.95% or more) of Example 2 and the ¹²C diamond (¹²C=99.95% or more) of Example 3 show the equal FWHM of a Raman peak as the above ¹²C diamond of Comparative Example 4 and have a high thermal conductivity. Boron is an impurity to diamond and decreases the thermal conductivity according to conventional technical common knowledge, however, the present invention shows that doping of boron has no influence upon thermal conductivity.

### Measurement of Thermal Conductivity 2

The measurement according to the FWHM of a Raman peak in the above measurement 2 is an indirect method, but the present measurement 2 is a direct method. As a device was employed a steady-state high thermal conductivity measurement device (TS/Lλ-8550, manufactured by Rigaku). As a sample was employed diamonds of 2×0.3×3 mm obtained in the above process of production. Both ends of a diamond sample were held by a golden probe (2×2×8 mm), and a temperature difference was provided on both ends of the probe. It was retained under a vacuum till it reached a steady state, and temperature gradients of the sample and the probes coated with a graphite paste in advance were measured by an infrared detector.

The thermal conductivity (λ_{Sample}) of the sample was calculated by the formula below according to the temperature gradient of the sample and that of the golden probe. In the formula (1), λ_{Au} denotes the thermal conductivity of the golden probe, (dT/dL)_{Au} and (dT/dL)_{Sample} denote the temperature gradient of the golden probe and that of the sample respectively, and A_{Au} and A_{Sample} denote the sectional area of the golden probe and that of the sample respectively. Table 3 shows typical examples of the thus obtained results.

The present measurement of thermal conductivity is conducted when the temperature of the sample is about 36° C., and since the scattering of phonons which interfere with the conduction of heat is smaller at a lower temperature, the measured value of thermal conductivity at room temperature is guessed to be higher.

Formula 1

TABLE 3

| | | ¹²C | | Thermal | |
|---|---|---|---|---|---|
| | Kind of | isotopic | | conductivity | Electrical |
| No. | diamond | ratio | Doping | (W/cm K) | characteristic |
| 1 | Diamond | 98.9% | Nil | 22.3 | Insulator |
| | with | | | | |
| | natural | | | | |
| | isotopic | | | | |
| | ratio | | | | |
| 2 | Diamond | ″ | ″ | 22.9 | ″ |
| | with | | | | |
| | natural | | | | |
| | isotopic | | | | |
| | ratio | | | | |
| 3 | Diamond | ″ | ″ | 22.6 | ″ |
| | with | | | | |
| | natural | | | | |
| | isotopic | | | | |
| | ratio | | | | |
| 4 | ¹²C diamond | ≧99.95% | Nil | 31.8 | Insulator |
| 5 | ″ | ″ | ″ | 31.8 | ″ |
| 6 | ″ | ″ | ″ | 29.9 | ″ |
| 7 | Diamond | 98.9% | Boron = | 23.9 | p-type |
| | with | | 3˜4 | | semiconductor |
| | natural | | ppm | | |
| | isotopic | | | | |
| | ratio | | | | |
| | containing | | | | |
| | boron | | | | |
| 8 | ¹²C diamond | ≧99.95% | Boron = | 30.6 | p-type |
| | containing | | 3˜4 | | semiconductor |
| | boron | | ppm | | |
| 9 | ¹²C diamond | ″ | Boron = | 28.0 | p-type |
| | containing | | 30˜40 | | semiconductor |
| | boron | | ppm | | |

As is apparent from Table 3, the diamond with a natural isotopic ratio containing no boron is an insulator for its electrical characteristic, and exhibits a thermal-conductive characteristic of a thermal conductivity of about 23 W/cm K. The diamond with a natural isotopic ratio containing boron is a p-type semiconductor for its electrical characteristic, and the thermal conductivity thereof is about 24 W/cm K. In contrast, the ¹²C purified diamond (¹²C isotope≧99.95%) containing boron of from 3 to 4 ppm is a p-type semiconductor and exhibits a thermal-conductive characteristic of a thermal conductivity of about 31 W/cm K, and the same ¹²C purified diamond, which contains boron of from 30 to 40 ppm, exhibits an excellent value of a thermal conductivity of about 28 W/cm K. The reason why the amount of boron doped ranges from 30 to 40 ppm is that boron was distributed in the sample within this range.

### Example 6

An RF plasma CVD device (RPS-0404 made of Nippon RF Co. Ltd.) was used as a device for producing a film. Film synthesis conditions were as described in Table 4. Methane (¹²CH₄) of ¹²C isotopic purification of 99.95% was used as CH₄ for synthesis, and 1000 ppm (=B/C) of B(CH₅)₅ was added for doping boron, thereby producing a diamond film.

An RF plasma CVD film obtained by the above device was analyzed, and the result revealed the quality of a diamond excellent in Raman spectrum analysis and cathode luminescence analysis.

TABLE 4

| Film Synthetic Parameter | Film Synthetic Condition |
|---|---|
| Power of RF | 45 kW |
| Pressure | 26.7 kPa (200 Torr) |
| Gas and Flow Rate | Ar: 31.8 1/min |
| | H₂: 11.2 1/min |
| | CH₄: 0.17 1/min |
| | B(CH₃)₃: 1000 ppm (= B/C) |
| Concentration of Methane | 0.4 vol% of Flow Rate of |
| | Entire Raw Material Gas |
| Substrate Temperature | 900 ° C. |
| Substrate Holder | Suction Type Holder Made of |
| | Copper |
| Substrate | Mo Plate: 50 mm φ |
| | (thickness = 5 mm) |

### Comparative Example 5

In the same manner as Example 1, using methane with a natural isotopic ratio containing methane as CH₄ for synthesis among a film synthesis condition in the Table 4, adding 1000 ppm (=B/C) of B(CH₃)₃, thereby producing a diamond film.

### Comparative Example 6

In the same manner as the Comparative Example 5 except for the non-addition of B(CH₃)₃, methane (¹²CH₄) of ¹²C isotopic purification of 99.95% has used as CH₄ for synthesis, thereby producing a diamond film.

### Comparative Example 7

In the same manner as the Comparative Example 5 except for the non-addition of B(CH₃)₃, natural isotopic methane with a natural isotopic ratio containing methane was used as CH₄ for synthesis, thereby producing a diamond film.

Measurement of the Amount of Boron:

The measurement was conducted using the same measuring device as the device for measuring amounts of boron of a high-pressure synthetic diamond of the first example.

Measurement of Thermal Conductivity:

The measurement was conducted using the measuring device as the device for measuring thermal conductivity of a high-pressure synthetic diamond of the first example.

As a method of processing a sample, the diamond film obtained by a pre-processing process was cut to a size of 2 mm×3 mm (width×length), also of 2 mm×4 mm and they are respectively polished by the depth of 20 μm from the back side of the film, thereby respectively producing two samples serving as samples for measuring thermal conductivity.

Result of Measurement of Thermal Conductivity of the CVD Diamond

Table 5 shows a result of measurement of a thermal conductivity of samples produced by the CVD method.

As evident from Table 5, the diamond with a natural isotopic ratio represents an insulator for its electrical characteristic, and also represents a thermal conductivity of 21 W/cm•K. The diamond with a natural isotopic ratio containing boron is a p-type semiconductor for its electrical characteristics, and the thermal conductivity thereof is about 20 W/cm•K. On the other hand, the ¹²C purified diamond containing boron of 20 ppm is a p-type semiconductor for its electrical characteristics, and also it has an excellent thermal conductivity of 26 W/cm•K.

TABLE 5

| | | ¹²C | Presence | Thermal | Electrical |
|---|---|---|---|---|---|
| | Kind of | isotopic | of | conductivity | Charact- |
| No. | Diamond | ratio | Doping | (W/cm.K) | eristic |
| Comp. | Diamond | 98.9% | None | 20.5 | Insulator |
| Ex. 7 | with | | | | |
| | Natural | | | | |
| | Isotopic | | | | |
| | ratio | | | | |
| Comp. | ¹²C | ≧99.95% | None | 27.5 | Insulator |
| Ex. 6 | Diamond | | | | |
| Comp. | Diamond | 98.9% | Boron = | 19.5 | P-type |
| Ex. 5 | with | | 20 ppm | | |
| | Natural | | | | |
| | Isotopic | | | | |
| | Ratio | | | | |
| | Containing | | | | |
| | Boron | | | | |
| Exam- | ¹²C | ≧99.95% | Boron = | 26.2 | P-type |
| ple | Diamond | | 20 ppm | | Semicon- |
| 6 | Containing | | | | ductor |
| | Boron | | | | |

According to the present invention, a ¹²C or ¹³C isotopic diamond which is boron-doped and has an extremely high thermal conductivity can be obtained. Said ¹²C isotopic diamond or ¹³C isotopic diamond which is boron-doped and has a high thermal conductivity is an excellent material in a utility related to heat, such as a semiconductor device and a luminescent device.

What is claimed is:

1. A ¹²C or ¹³C isotopic diamond which is boron-doped, has a high thermal conductivity and is isotopically purified.

2. A ¹²C or ¹³C isotopic diamond which is boron-doped, has a high thermal conductivity and is isotopically purified as claimed in claim 1, wherein the purity of the ¹²C or ¹³C isotope of said isotopic diamond is at least 99.5%.

3. A ¹²C or ¹³C isotopic diamond which is boron-doped, has a high thermal conductivity and is isotopically purified as claimed in claim 1, wherein the purity of the ¹²C or ¹³C isotope of said isotopic diamond is at least 99.5% and said high thermal conductivity is higher than that of a high-purity diamond with a natural isotopic ratio at room temperature by 15-50%.

4. A ¹²C or ¹³C isotopic diamond which is boron-doped, has a high thermal conductivity and is isotopically purified as claimed in claim 1, wherein the concentration of said boron is less than 100 ppm.

5. A ¹²C or ¹³C isotopic diamond which is boron-doped, has a high thermal conductivity and is isotopically purified as claimed in claim 3, wherein said high thermal conductivity is higher than that of a high-purity diamond with a natural isotopic ratio at room temperature by 30-50%.

6. A luminescent device comprising a ¹²C or ¹³C isotopic diamond which is boron-doped, has a high thermal conductivity and is isotopically purified.

7. A semiconductor device comprising a ¹²C or ¹³C isotopic diamond which is boron-doped, has a high thermal conductivity and is isotopically purified.

8. A process for producing a ¹²C or ¹³C isotopic diamond single crystal, comprising providing a carbon containing isotopically purified ¹²C or ¹³C as a material, employing a flux containing a nitrogen getter, adding boron into said carbon material and/or the flux, or around said carbon material and the flux, and diffusing said carbon material into the flux under a high pressure and a high temperature, whereby a boron-doped diamond single crystal is formed on a seed crystal diamond.

9. A process for producing a ¹²C or ¹³C isotopic diamond single crystal as claimed in claim 8, wherein the purity of the ¹²C or ¹³C isotope of said material carbon is at least 99.5%.

10. A process for producing a ¹²C or ¹³C isotopic diamond single crystal as claimed in claim 8, wherein the concentration of said boron is less than 100 ppm.

11. A process for producing a ¹²C or ¹³C isotopic diamond single crystal as claimed in claim 8, wherein said material carbon is a pyrolytic carbon, a diamond synthesized by chemical deposition, or a diamond-like carbon synthesized by chemical decomposition.

12. A process for producing a ¹²C or ¹³C isotopic diamond which is boron-doped and has a high thermal conductivity, comprising providing a mixed gas of an isotopically purified hydrocarbon or carbon monoxide or carbon dioxide containing ¹²C or ¹³C or a mixed gas of at least two thereof and hydrogen, adding a doping component thereto, and forming a diamond in a thin-film state on a substrate in the presence of a reaction atmosphere.

13. A process for producing a ¹²C or ¹³C isotopic diamond which is boron-doped and has a high thermal conductivity as claimed in claim 11, wherein the hydrocarbon comprising isotopically purified ¹²C or ¹³C is ¹²CH₄ or ¹³CH₄.

14. A ¹²C or ¹³C isotopic diamond which is boron-doped, has a high thermal conductivity and is isotopically purified as claimed in claim 1, wherein said high thermal conductivity is from about 26-31 W/cm ° K.

15. A process for producing a ¹²C or ¹³C isotopic diamond single crystal as claimed in claim 8, wherein said isotopic diamond single crystal has a thermal conductivity from about 26-31 W/cm ° K.

16. A process for producing a ¹²C or ¹³C isotopic diamond which is boron-doped and has a high thermal conductivity as claimed in claim 12, wherein said high thermal conductivity is from 26-31 W/cm ° K.
